(19) United States
(12) Patent Application Publication
(10) Pub. No.: US 2024/0372171 A1
(43) Pub. Date: Nov. 7, 2024

(54) DEVICE, SYSTEM, AND METHOD TO CONTROL AT LEAST ONE ELECTRICAL CIRCUIT TO ENTER A LOW EFFICIENCY MODE TO HEAT A BATTERY CELL

(71) Applicant: MOTOROLA SOLUTIONS, INC., Chicago, IL (US)

(72) Inventors: Yoke Peir LIM, Bayan Lepas (MY); Yen Nee LEE, Sungai Ara (MY); Daniel TAN, Tanjung Bungah (MY); May San LOO, Prai (MY); Kee Sin THONG, Butterworth (MY); Wai Mun LEE, Ipoh (MY)

(21) Appl. No.: 18/142,171

(22) Filed: May 2, 2023

(51) Int. Cl. H01M 10/633; G01R 31/389; H01M 10/44; H01M 10/48

(52) U.S. Cl. CPC H01M 10/633; G01R 31/389; H01M 10/443; H01M 10/486

(57) ABSTRACT

Device, system and method to control at least one electrical circuit to enter a low efficiency mode to heat a battery cell is provided. A temperature measurement device and battery cell parameter determination device respectively determine a temperature and impedance of a battery cell of a device. When the temperature of the battery cell is below a threshold temperature and the impedance of the battery cell is above a threshold impedance, a controller of the device controls at an electrical circuit of the device to enter a low efficiency mode by controlling the electrical circuit to draw an auxiliary current from the battery cell to heat the battery cell, the auxiliary current being below a given functional operating current of the electrical circuit, the electrical circuit having reduced functionality, relative to a given functionality when drawing a given functional operating current from the battery cell, while drawing the auxiliary current.

### BACKGROUND OF THE INVENTION

Batteries are generally used to power portable devices, however in lower temperatures (e.g., −20 C, −30 C) performance of a battery may be degraded due to a high impedance of a battery cell at lower temperatures. When a portable device that incorporates a battery cell is used at such lower temperatures, such high impedance of the battery cell may reduce the lifetime of the battery cell, and/or render the portable device inoperable, and/or cause a battery tripping circuit to trip, and hence reduce a time that the portable device may be used (e.g., before the battery cell warms up due to ambient temperature warming and/or before swapping out the battery cell for a new battery cell). Such an issue may be particularly important when such portable devices are used by first responders when such portable devices are used in harsh, low temperature environments.

### BRIEF DESCRIPTION OF THE SEVERAL VIEWS OF THE DRAWINGS

The accompanying figures, where like reference numerals refer to identical or functionally similar elements throughout the separate views, together with the detailed description below, are incorporated in and form part of the specification, and serve to further illustrate embodiments of concepts that include the claimed invention, and explain various principles and advantages of those embodiments.

FIG. 1 depicts a front view of a device to control at least one electrical circuit to enter a low efficiency mode to heat a battery cell, in accordance with some examples.

FIG. 2 is a device diagram showing a device structure of a device to control at least one electrical circuit to enter a low efficiency mode to heat a battery cell, in accordance with some examples.

FIG. 3 is a flowchart of a method to control at least one electrical circuit to enter a low efficiency mode to heat a battery cell, in accordance with some examples.

FIG. 4 is a flowchart of a method to control at least one electrical circuit to enter a heating mode to heat the at least one electrical circuit and/or an adjacent integrated circuit, in accordance with some examples.

FIG. 5 depicts an example of the device of FIG. 1 and FIG. 2 in a normal operating mode, in accordance with some examples.

FIG. 6 depicts the example of FIG. 5, with the device controlling at least one electrical circuit to enter a low efficiency mode to heat a battery cell, in accordance with some examples.

FIG. 7 depicts the example of FIG. 5, with the device controlling at least one electrical circuit to enter a heating mode to heat the at least one electrical circuit and/or an adjacent integrated circuit, in accordance with some examples.

FIG. 8 depicts the device of FIG. 1 showing a graphic user interface to control at least one electrical circuit to enter a low efficiency mode to heat a battery cell, in accordance with some examples.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

The apparatus and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

### DETAILED DESCRIPTION OF THE INVENTION

Batteries are generally used to power portable devices, however in lower temperatures (e.g., −20 C, −30 C) performance of a battery may be degraded due to a high impedance of a battery cell at lower temperatures. When a portable device that incorporates a battery cell is used at such lower temperatures, such high impedance of the battery cell may reduce the lifetime of the battery cell, and/or render the portable device inoperable, and/or cause a battery tripping circuit to trip, and hence reduce a time that the portable device may be used (e.g., before the battery cell warms up due to ambient temperature warming and/or before swapping out the battery cell for a new battery cell). Such an issue may be particularly important when such portable devices are used by first responders when such portable devices are used in harsh, low temperature environments. While such portable devices may be adapted to include battery heaters, such battery heaters add to the cost of a device, and furthermore, a manufacturing process for the device may need to be altered to incorporate such battery heaters, and/or a board layout and/or component layout may need to be altered to incorporate such battery heaters. Thus, there exists a need for an improved technical method, device, and system to control at least one electrical circuit to enter a low efficiency mode to heat a battery cell.

Such an improved technical method, device, and system may specifically exclude incorporation of a battery heater, or other types of heaters, into the device and/or system.

Hence, provided herein is a device, system and method to control at least one electrical circuit to enter a low efficiency mode to heat a battery cell. In some aspects of the present specification, a system is provided that includes a portable device and a battery cell, which may be insertable into, and removable, from the portable device. In other aspects of the present specification, a portable device is provided that includes a battery cell, which may, or may not, be changeable at the portable device. Hereafter, for simplicity, reference will be made to a device that is understood to include a system of a portable device and a battery cell.

Hence, a device as provided herein includes a battery cell. As described herein, the device may comprise a portable radio, and the like, which may be used by first responders, though any suitable portable device and/or a device that that is powered by a battery cell, is within the scope of the present specification.

The device may comprise a temperature measurement device configured to measure a temperature of the battery cell, and a battery cell parameter determination device configured to determine at least an impedance of the battery cell. However, the battery cell parameter determination device may be configured to determine other parameters of the battery cell, including, but not limited to, a voltage of the battery cell, a charge capacity of the battery cell, and the like. In some examples, the temperature measurement device and/or the battery cell parameter determination device may be components of the battery, and a controller of the device may communicate with the temperature measurement device and/or the battery cell parameter determination device of the battery via one or more data connections, and the like.

The device further comprises at least one electrical circuit configured to provide given functionality (e.g., to the device) when drawing a given functional operating current from the battery cell. The given functional current may enable the at least one electrical circuit to provide the given functionality in a normal operating mode of the device. It is understood that, in some examples, and which may depend on a type of the at least one electrical circuit, when the at least one electrical circuit is drawing an electrical current below the given functional operating current, the at least one electrical circuit may not be enabled to provide the given functionality.

For example, the at least one electrical circuit may comprise a radio-frequency (RF) transmit amplifier, which may be used to amplify power of RF signals for transmission (e.g., via a transceiver). When the RF transmit amplifier is drawing the given functional current from the battery cell, the RF transmit amplifier may amplify such RF signals (into which is encoded voice data received via a microphone of the device) to a level suitable for transmission by a transceiver of the device. However, when the RF transmit amplifier is drawing a current that is less than the given functional current from the battery cell, the RF transmit amplifier may also amplify such RF signals, but not to a level suitable for transmission.

The device may further generally include a controller (e.g., a processing module, and the like), which may communicate with the temperature measurement device and the battery cell parameter determination device to respectively determine a temperature and impedance of the battery cell, and compare the temperature and impedance of the battery cell to respective thresholds. When the temperature of the battery cell is below a threshold temperature and the impedance of the battery cell is above a threshold impedance, the controller may control the at least one electrical circuit to enter a low efficiency mode by controlling the at least one electrical circuit to draw an auxiliary current from the battery cell to heat the battery cell, the auxiliary current being below the given functional operating current, the at least one electrical circuit having reduced functionality, relative to the given functionality, while drawing the auxiliary current. Such heating of the battery cell is understood to be due to IR (electrical current×impedance and/or resistance) loss in the battery cell.

Put another way, while the auxiliary current is being drawn from the battery cell, overall functionality of the device may be reduced, however, the auxiliary current from the battery cell may cause the battery cell to emit heat due to IR loss, which increases the temperature of the battery cell, which in turn decreases the impedance of the battery cell. Once the impedance of the battery cell reaches a given impedance, for example, at or below the threshold impedance, the controller may control the at least one electrical circuit to exit the low efficiency mode and draw the given functional operating current from the battery cell.

Hence, without adapting the device to include a battery heater, the device may be operated to heat the battery cell to a temperature where the impedance of the battery cell is below the threshold impedance.

An aspect of the present specification provides a device comprising: a battery cell: at least one electrical circuit configured to provide given functionality when in drawing a given functional operating current from the battery cell: a temperature measurement device configured to measure a temperature of the battery cell: a battery cell parameter determination device configured to determine at least an impedance of the battery cell; and a controller configured to: determine, via the temperature measurement device, the temperature of the battery cell: determine, via the battery cell parameter determination device, the impedance of the battery cell; and, when the temperature of the battery cell is below a threshold temperature and the impedance of the battery cell is above a threshold impedance: control the at least one electrical circuit to enter a low efficiency mode by controlling the at least one electrical circuit to draw an auxiliary current from the battery cell to heat the battery cell, the auxiliary current being below the given functional operating current, the at least one electrical circuit having reduced functionality, relative to the given functionality, while drawing the auxiliary current.

Another aspect of the present specification provides a method comprising: determining, via a temperature measurement device, a temperature of a battery cell of a device: determining, via a battery cell parameter determination device, an impedance of the battery cell; and, when the temperature of the battery cell is below a threshold temperature and the impedance of the battery cell is above a threshold impedance: controlling, via a controller of the device, at least one electrical circuit of the device to enter a low efficiency mode by controlling the at least one electrical circuit to draw an auxiliary current from the battery cell to heat the battery cell, the auxiliary current being below a given functional operating current of the at least one electrical circuit, the at least one electrical circuit having reduced functionality, relative to a given functionality when drawing a given functional operating current from the battery cell, while drawing the auxiliary current.

Each of the above-mentioned aspects will be discussed in more detail below, starting with example system and device architectures of the system, in which the embodiments may be practiced, followed by an illustration of processing blocks for achieving an improved technical method, device, and system to control at least one electrical circuit to enter a low efficiency mode to heat a battery cell.

Example embodiments are herein described with reference to flowchart illustrations and/or block diagrams of methods, apparatus (systems) and computer program products according to example embodiments. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a special purpose and unique machine, such that the instructions, which execute via the processor of the computer or other programmable data processing apparatus, create means for implementing the functions/acts specified in the flowchart and/or block diagram block or blocks. The methods and processes set forth herein need not, in some embodiments, be performed in the exact sequence as shown and likewise various blocks may be performed in parallel rather than in sequence. Accordingly, the elements of methods and processes are referred to herein as “blocks” rather than “steps.”

These computer program instructions may also be stored in a computer-readable memory that can direct a computer or other programmable data processing apparatus to function in a particular manner, such that the instructions stored in the computer-readable memory produce an article of manufacture including instructions, which implement the function/act specified in the flowchart and/or block diagram block or blocks.

The computer program instructions may also be loaded onto a computer or other programmable data processing apparatus that may be on or off-premises, or may be accessed via the cloud in any of a software as a service (Saas), platform as a service (PaaS), or infrastructure as a service (IaaS) architecture so as to cause a series of operational blocks to be performed on the computer or other programmable apparatus to produce a computer implemented process such that the instructions, which execute on the computer or other programmable apparatus provide blocks for implementing the functions/acts specified in the flowchart and/or block diagram block or blocks. It is contemplated that any part of any aspect or embodiment discussed in this specification can be implemented or combined with any part of any other aspect or embodiment discussed in this specification.

Further advantages and features consistent with this disclosure will be set forth in the following detailed description, with reference to the drawings.

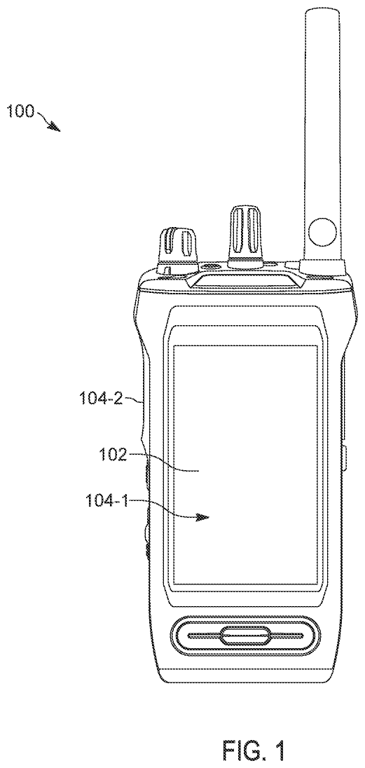

Attention is directed to FIG. 1, which depicts front view of an example device 100 to control at least one electrical circuit to enter a low efficiency mode to heat a battery cell. While the battery cell is not depicted (e.g., the battery cell is understood to be internal to the device 100), the device 100 is nonetheless understood to include the battery cell.

As depicted, the device 100 comprises a portable radio, however, the device 100 may comprise any suitable device that is powered by a battery cell.

As depicted, the device 100 includes a display screen 102 and at least one input device 104-1, 104-2, such as a touch screen of the display screen 102 (e.g., the input device 104-1) and/or one or more buttons or knobs, such as a push-to-talk (PTT) button, and the like (e.g., the input device 104-2). However the display screen 102 may be optional, and at least one input device 104-1, 104-2 may comprise any suitable input device and/or combinations of input devices. For simplicity, the at least one input device 104-1, 104-2 are interchangeably referred to hereafter, collectively, as the input devices 104, and, generically, as an input device 104.

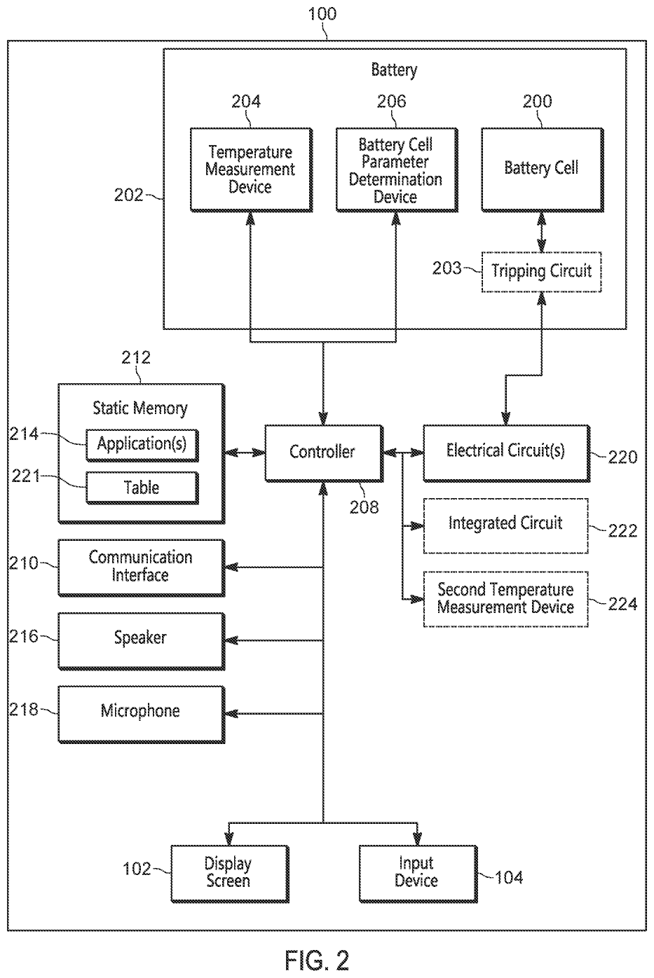

Attention is next directed to FIG. 2, which depicts a schematic block device diagram showing an example device structure of the device 100.

As depicted, the device 100 comprises a battery cell 200, which, as depicted, is a component of a battery 202 that also includes an optional battery tripping circuit 203, a temperature measurement device 204 configured to measure a temperature of the battery cell 200 and a battery cell parameter determination device 206 configured to determine at least an impedance of the battery cell 200.

However, alternatively, and/or in addition, the battery cell parameter determination device 206, and/or a portion thereof, may be incorporated into the device 100 separate from the battery 100. Put another way, at least a portion of the battery cell parameter determination device 206 may not be located in the battery 202, but in another region of the device 100. For example, an impedance measurement determination component, of the battery cell parameter determination device 206, may be located in the device 100, but not in the battery 202 and/or such an impedance measurement determination component may be a component separate from the battery cell parameter determination device 206, which may measure other parameters of the battery cell 200, such as voltage. Put yet another way, the device 100 is understood to comprise the battery 202 that includes the battery cell 202, and at least a portion of the battery cell parameter determination device 206 may be located external to the battery 202, but within the device 100.

However, the temperature measurement device 204 may be at least partially located internal to the battery 202.

The battery cell 200 may comprise any suitable battery cell type, including, but not limited to, a nickel-cadmium battery cell, a nickel-metal hydride battery cell, a lithium-ion battery cell, lithium-polymer battery cell, and the like, and may be rechargeable. In general, the battery cell 200 provides power to the components of the device 100 to power the device 100, and may be rated at a particular voltage rating (e.g., such as 12V, and the like), a particular charge capacity and/or energy density, and the like.

The battery tripping circuit 203 may cause power provided by the battery cell 200 to stop being provided when components of the device 100 attempt to draw power, and the like, from the battery cell 200 that is above a threshold power, and the like, and/or when a voltage drop across the battery cell 200, due a current being drawn from the battery cell 200 and an impedance of the battery cell 200, is above a threshold voltage drop (e.g., a threshold IR loss in the battery cell 200).

The temperature measurement device 204 may comprise a thermistor based device configured to measure a temperature of the battery cell 200 using a thermistor, and the like.

The battery cell parameter determination device 206 may comprise any suitable combination of one or more electrical measurement devices and/or circuits, which measure one or more electrical parameters of the battery cell 200 including an impedance of the battery cell 200. The battery cell parameter determination device 206 may further measure a voltage and/or a charge capacity of the battery cell 200, amongst other possibilities. In particular, the impedance of the battery cell 200 may increase as temperature of the battery cell decreases, and the voltage and/or a charge capacity of the battery cell 200 may also change with time and/or temperature.

Such an increase in impedance leads to higher IR losses in the battery cell 200, which may reduce an amount of voltage available by the battery cell 200 to power the device 100. In some of these examples, such an increase may cause the battery tripping circuit 203 to trip. However, when the battery tripping circuit 203 is not present, the device 100 may fail to operate, as the voltage output by the battery cell 200 may fall below a respective operating voltage of components of the device 100 (e.g., a minimum voltage that a component of the device 100 may require to function and/or turn on).

For example, the battery cell 200 may be rated at a given voltage “V” (e.g., 12V, 15V, amongst other possibilities), but a voltage, “Vout”, is provided by the battery cell 200 to the components of the device 100, including, but not limited to, the at least one electrical circuit 220. In general:

$$V out = V - I \times Rbat \qquad Equation ( 1 )$$

In Equation (1), “I” comprises the current drawn by device 100 from the battery cell 200, and “Rbat” comprises the impedance of the battery cell 200. Hence, for a given voltage “V”, and a given current “I”, Vout decreases as Rbat increases, for example as temperature decreases. When Vout falls below a respective operating voltage of components of the device 100, such components may fail to operate.

In some examples, the respective operating voltage of components of the device 100 may be the same or different.

As depicted, the device 100 further comprises the display screen 102, the at least one input device 104, a controller 208, a communication interface 210, and a static memory 212 storing at least one application 214, interchangeably referred to hereafter as the application 214. As the device 100 may comprise a portable radio, as depicted the device 100 further comprises a speaker 216 and a microphone 218.

While not depicted, the controller 208 may be a component of a processing module that includes a Random-Access Memory (RAM), a code Read Only Memory (ROM), and a common data and address bus. Indeed, other components of the device 100 may be in communication with the controller 208 via a common data and address bus.

While not depicted, the communication interface 210 may comprise one or more transceivers, one or more wired and/or wireless input/output (I/O) interfaces, and a combined modulator/demodulator.

As depicted, the device 100 further comprises at least one electrical circuit 220 configured to draw current from the battery cell 200. In particular, the at least one electrical circuit 220 is configured to provide given functionality when drawing a given functional operating current from the battery cell 200, for example when Vout of Equation (1) is at least a minimum value. Such given functionality may generally depend on a respective type of the at least one electrical circuit 220.

For example, at least one electrical circuit 220 may comprise one or more of:
A MOSFET (metal-oxide semiconductor field-effect transistor) with biasing control capability. For example, a MOSFET is generally understood to draw a bias current that controls biasing of the MOSFET. The given functional operating current of a MOSFET may comprise a bias current to control the MOSFET. Such a MOSFET may be a component of an amplifier of the device 100.
An RF transmit amplifier, which may comprise a MOSFET (e.g., with biasing control capability). Such an RF transmit amplifier may be configured to amplify signals received by the microphone 218 of the device 100, for example for transmission by the communication interface 210.
An audio amplifier, which may comprise a MOSFET (e.g., with biasing control capability). Such an audio amplifier may be configured, for example for processing by a baseband processor (which may also be a component of the at least one electrical circuit 220), to extract data therefrom and/or for playing by the speaker 216. Hence, the audio amplifier may be interchangeably referred to as an RF receive amplifier.
A regulator, such as a low-dropout (LDO) regulator, which may regulate voltage for use by other components of the device 100.
A baseband processor, which may implement radio protocols and/or convert digital data into radio frequency signals (and vice-versa), which may then be transmitted over wireless network. Such a baseband processor may be in communication with the audio amplifier and the RF transmit amplifier to convert digital data into radio frequency signals (and vice-versa).
An applications processor, which implement an operating system of the device 100, and/or implement other (e.g., user) applications of the device 100.
An RF integrated circuit and/or synthesizer that may interact with the baseband processor.

Hence, while the at least one electrical circuit 220 is depicted as being separate from other components of the device 100, depending on a type of the at least one electrical circuit 220, an electrical circuit 220 may be combined with other components of the device 100 and/or other electrical circuit 220. For example, an RF transmit amplifier and/or an audio amplifier (e.g., an RF receive amplifier) of the at least one electrical circuit 220 may be incorporated into the communication interface 210. Similarly, a baseband processor and/or an applications processor may be combined, or at least partially combined, with the controller 208, and/or a processing module that includes the controller 208 as a component thereof.

However, the at least one electrical circuit 220 may comprise any suitable electrical circuit and/or combination thereof.

Furthermore, it is understood that the device 100 and/or the at least one electrical circuit 220 specifically excludes a dedicated battery cell heater and a dedicated device heater, and the like.

As will be described herein, the at least one electrical circuit 220 may be operated in a low efficiency mode, by controlling the at least one electrical circuit 220 to draw an auxiliary current from the battery cell 200 to heat the battery cell 200, the auxiliary current being below the given functional operating current, the at least one electrical circuit 220 having reduced functionality, relative to the given functionality, while drawing the auxiliary current.

Certain constraints may be placed on the auxiliary current.

In some examples, the auxiliary current may comprise a current below (e.g., lower than) the given functional operating current, that does not cause the battery tripping circuit 203, when present, to trip.

In other examples, the auxiliary current may comprise a current below (e.g., lower than) the given functional operating current, that produces an IR loss in the battery cell 200 that heats the battery cell 200.

In yet further examples, the auxiliary current may comprise a current below (e.g., lower than) the given functional operating current, that produces an IR loss in the battery cell 200 that further enables the battery cell 200 to provide a voltage, Vout, that is at, and/or higher than, a respective operating voltage of other components of the device 100, such as the controller 208, so that the controller 208 may control at least the at least one electrical circuit 220 accordingly.

For example, Equation (1) may be written to include the given functional operating current, “IGfoc” and the auxiliary current, “IAux” respectively:

$$V out Gfoc = V - IGFoc \times Rbat \qquad Equation ( 2 )$$

$$V out Aux = V - IAux \times Rbat \qquad Equation ( 3 )$$

In Equation (2), “VoutGfoc” comprises a voltage provided by the battery cell 200 when the given functional operating current, IGFoc, is drawn from the battery cell 200, having an impedance “Rbat”.

Similarly, in Equation (3), “VoutAux” comprises a voltage provided by the battery cell 200 when the auxiliary current, IAux, is drawn from the battery cell 200, having the impedance “Rbat”.

In each of Equation (2) and Equation (3), “V” comprises the voltage rating of the battery cell 200, similar to Equation (1).

As the auxiliary current, IAux, is less than the given functional operating current, IGFoc, it is understood that the voltage, VoutAux, provided by the battery cell 200, when the auxiliary current, IAux, is drawn from the battery cell 200, is greater than the voltage, VoutGfoc, provided by the battery cell 200 when the given functional operating current, IGFoc, is drawn from the battery cell 200. In general, the auxiliary current may be selected such that the voltage, VoutAux, provided by the battery cell 200 when the auxiliary current, IAux, is greater than an operating voltage of at least a portion of the components of the device 100, and in particular the controller 208, the memory 212, the communication interface 210, amongst other possibilities.

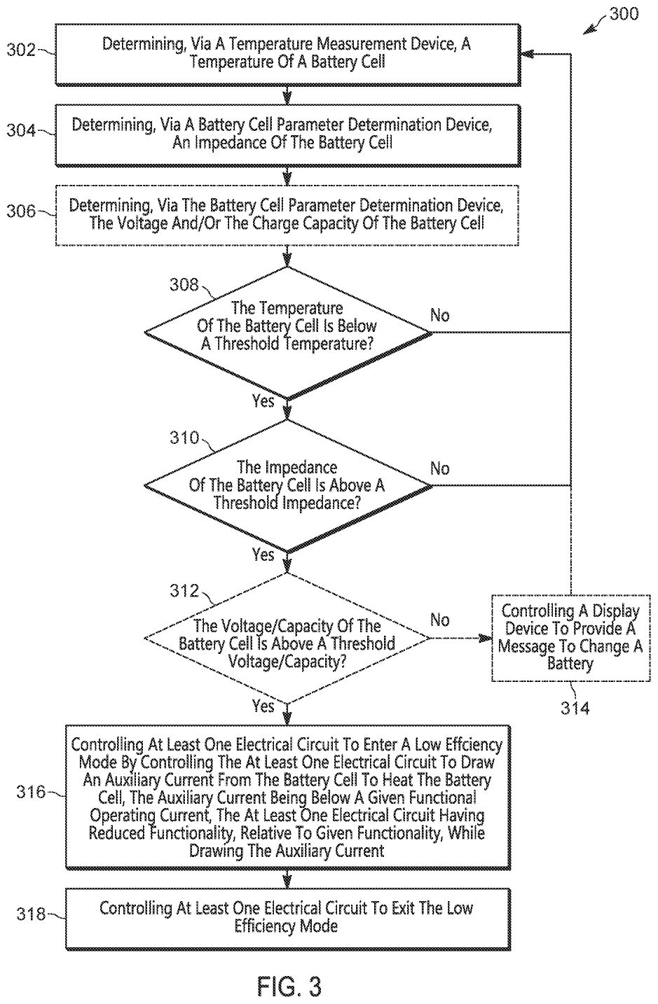

The at least one electrical circuit 220 may enter, and leave, the low efficiency mode, under control by the controller 208, as described in more detail with respect to FIG. 3.

However, it is understood that at least one electrical circuit 220 may enter the low efficiency mode, under control by the controller 208, when the device 100 is turned on, and/or after the device 100 has been turned on and has been in operation for a period of time.

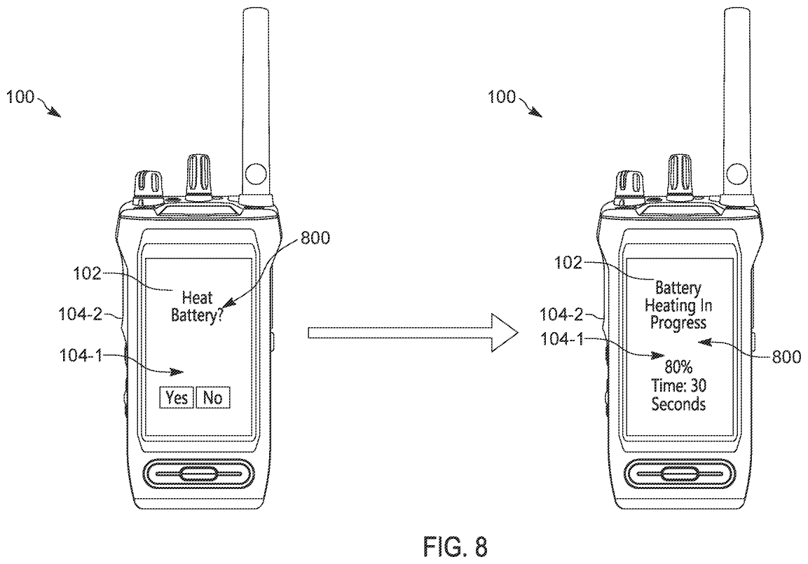

In examples, where the device 100 is turned on, the temperature of the battery cell 200 may already be below a threshold temperature for entering the low efficiency mode, and the impedance of the battery cell 200 may already be above the threshold impedance. In particular, the device 100 may have been stored at an ambient temperature that is below the threshold temperature, and hence a temperature of the battery cell 200, when the device 100 is turned on, may be below the threshold temperature. In some of these examples, when the device 100 is turned on, the controller 208 may control the at least one electrical circuit 220 to enter the low efficiency mode automatically when the device 100 is turned on, and the temperature is below the threshold temperature and the impedance of the battery cell 200 is above the threshold impedance. However, in other examples, the controller 208 may provide a query (e.g., at a graphic user interface at the display screen 102, and the like) when the device 100 is turned on, as to whether, or not, the controller 208 is to control the at least one electrical circuit 220 to enter the low efficiency mode, and a user of the device 100 may operate an input device 104 to cause the controller 208 to control the at least one electrical circuit 220 to enter the low efficiency mode. An example of such a query is depicted in FIG. 8, described herein.

However, in other examples, after the device 100 has been in operation for a period of time, and the temperature of the battery cell 200 is initially above the threshold temperature and/or the impedance of the battery cell 200 is below the threshold impedance, over time, the temperature of the battery cell 200 may drift below the threshold temperature for entering the low efficiency mode, and the impedance of the battery cell 200 may drift upwards, above the threshold impedance. In some of these examples, the controller 208 may control the at least one electrical circuit 220 to enter the low efficiency mode automatically when the temperature is below the threshold temperature and the impedance of the battery cell 200 is above the threshold impedance. However, in other examples, the controller 208 may provide a query (e.g., at the display screen 102, and the like) as to whether, or not, the controller 208 is to control the at least one electrical circuit 220 to enter the low efficiency mode, and a user of the device 100 may operate an input device 104 to cause the device 100 to control the at least one electrical circuit 220 to enter the low efficiency mode. An example of such a query is depicted in FIG. 8, described herein.

Hence, the controller 208 may determine the temperature and impedance of the battery cell 200 when the device 100 is turned on, and/or the controller 208 may monitor the temperature and impedance of the battery cell 200 over time, and the controller 208 may control the at least one electrical circuit 220 to enter the low efficiency mode when the temperature is below the threshold temperature and the impedance is above the threshold impedance.

For example, as depicted, the memory 212 further stores a table 221, and the like, which may store one or more threshold impedances that may be dependent on one or more of a threshold temperature and a type of the battery cell 200. For example, as has been describe herein, an impedance of the battery cell 200 may increase as temperature of the battery cell 200 decreases, and such an increase of the impedance may depend on a type of the battery cell 200. Furthermore, as also described herein, the at least one electrical circuit 220 may be controlled into the low efficiency mode when a temperature of the battery cell 200 is below a threshold temperature, and when the impedance of the battery cell 200 is above a threshold impedance. However some types of battery cells 200 may have lower threshold temperatures than other battery cells 200, which may be stored at the table 221; and similarly, some types of battery cells 200 may have higher threshold impedances than other battery cells 200.

Hence, such threshold temperatures and threshold impedances may be stored at the table 221 in association with given battery types. For example, for nickel-cadmium battery cell types, a threshold temperature may be higher (or lower) than for lithium-ion battery cell types, and a threshold impedance may be lower (or higher) than for lithium-ion battery cell types.

A type of the battery cell 200 may hence be stored at the battery 202, and readable by the controller 208 via a data connection to the battery 202. The controller 208 may process the table 221 to determine respective threshold temperatures and threshold impedances for the battery cell 200 using the type of the battery cell 200.

Similarly, the table 221 may store an auxiliary current to be drawn by the at least one electrical circuit 220, which may depend on an impedance of the battery cell 200, a type of the battery cell 200, a temperature of the battery cell 200, and/or a type of the at least one electrical circuit 220. Furthermore, the table 221 may store different auxiliary currents for different types of electrical circuits 220.

Alternatively, the table 221 may store a minimum voltage, VoutAux (e.g., of Equation (3)) provided by the battery cell 200 when an auxiliary current is to be drawn from the battery cell 200, and, using Equation (3), an auxiliary current, IAux, may be determined accordingly, for example from a measurement of an impedance of the battery cell 200.

The communication interface 210 may include one or more wired and/or wireless input/output (I/O) interfaces that are configurable to communicate with via one or more communication networks. For example, the communication interface 210 may include one or more wired and/or wireless transceivers. Hence, the one or more transceivers of the communication interface 210 may be adapted for communication with one or more communication links and/or communication networks used to communicate with the other components of one or more communication networks. For example, the one or more transceivers of the communication interface 210 may be adapted for communication with one or more of the Internet, a digital mobile radio (DMR) network, a Project 25 (P25) network, a terrestrial trunked radio (TETRA) network, a Bluetooth network, a Wi-Fi network, for example operating in accordance with an IEEE 802.11 standard (e.g., 802.11a, 802.11b, 802.11g), an LTE (Long-Term Evolution) network and/or other types of GSM (Global System for Mobile communications) and/or 3GPP (3rd Generation Partnership Project) networks, a 5G network (e.g., a network architecture compliant with, for example, the 3GPP TS 23 specification series and/or a new radio (NR) air interface compliant with the 3GPP TS 38 specification series) standard), a Worldwide Interoperability for Microwave Access (WiMAX) network, for example operating in accordance with an IEEE 802.16 standard, and/or another similar type of wireless network. Hence, the one or more transceivers may include, but are not limited to, a cell phone transceiver, a DMR transceiver, P25 transceiver, a TETRA transceiver, a 3GPP transceiver, an LTE transceiver, a GSM transceiver, a 5G transceiver, a Bluetooth transceiver, a Wi-Fi transceiver, a WiMAX transceiver, and/or another similar type of wireless transceiver configurable to communicate via a wireless radio network.

The communication interface 210 may further include one or more wireline transceivers, such as an Ethernet transceiver, a USB (Universal Serial Bus) transceiver, or similar transceiver configurable to communicate via a twisted pair wire, a coaxial cable, a fiber-optic link, or a similar physical connection to a wireline network.

The controller 208 may include ports (e.g., hardware ports) for coupling to other suitable hardware components.

The controller 208 may include one or more logic circuits, one or more processors, one or more microprocessors, one or more GPUs (Graphics Processing modules), and/or the controller 208 may include one or more ASIC (application-specific integrated circuits) and one or more FPGA (field-programmable gate arrays), and/or another electronic device. In some examples, the controller 208 and/or the device 100 is not a generic controller and/or a generic device, but a device specifically configured to implement functionality to control at least one electrical circuit to enter a low efficiency mode to heat a battery cell. For example, in some examples, the device 100 and/or the controller 208 specifically comprises a computer executable engine configured to implement functionality to control at least one electrical circuit to enter a low efficiency mode to heat a battery cell.

The static memory 212 comprises a non-transitory machine readable medium that stores machine readable instructions to implement one or more programs or applications. Example machine readable media include a non-volatile storage unit (e.g., Erasable Electronic Programmable Read Only Memory (“EEPROM”), Flash Memory) and/or a volatile storage unit (e.g., random-access memory (“RAM”)). In the example of FIG. 2, programming instructions (e.g., machine readable instructions) that implement the functionality of the device 100 as described herein are maintained, persistently, at the memory 212 and used by the controller 208, which makes appropriate utilization of volatile storage during the execution of such programming instructions.

Regardless, it is understood that the memory 212 stores instructions corresponding to the at least one application 214 that, when executed by the controller 208, enables the controller 208 to implement functionality to control at least one electrical circuit to enter a low efficiency mode to heat a battery cell, including, but not limited to, the blocks of the method set forth in FIG. 3.

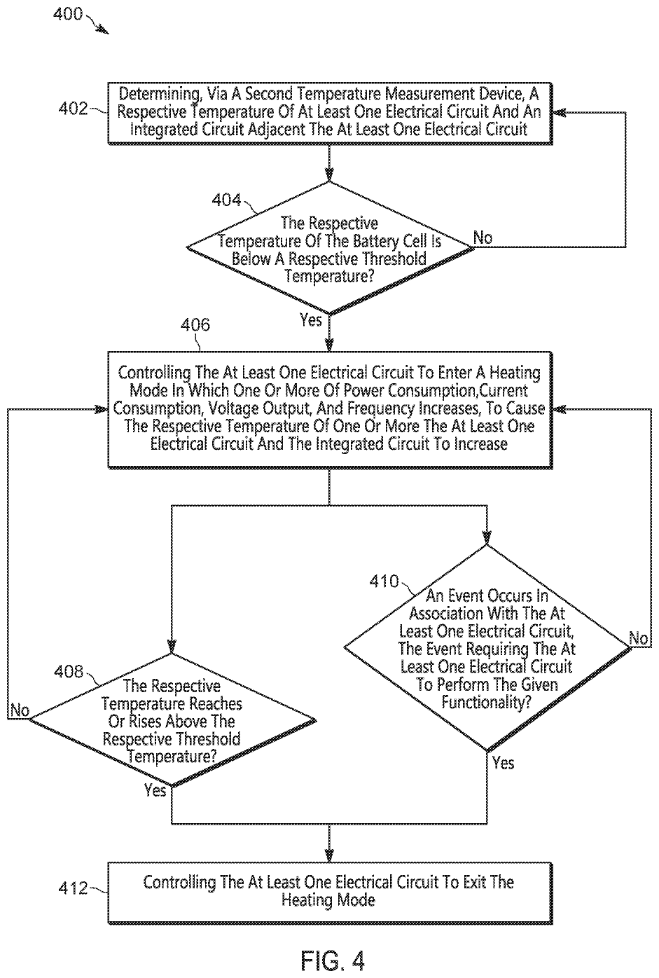

In other examples, the memory 212 may stores instructions corresponding to the at least one application 214 that, when executed by the controller 208, enables the controller 208 to implement functionality to control at least one electrical circuit to enter a heating mode to heat at least one electrical circuit and/or an integrated circuit adjacent the electrical circuit, including, but not limited to, the blocks of the method set forth in FIG. 4. Indeed, the blocks of the method set forth in FIG. 3 and the blocks of the method set forth in FIG. 4 may be stored in different modules of the at least one application 214.

The application 214 and/or the programming application 214 may include programmatic algorithms, and the like, to implement functionality as described herein using, for example, the table 221 to determine threshold temperatures, threshold impedance, auxiliary currents, and the like, for different types of the battery cell 200 and/or different types of the electrical circuit 200.

Alternatively, and/or in addition, application 214 and/or the programming application 214 may include one or more machine learning algorithms that may include, but are not limited to: a deep-learning based algorithm: a neural network: a generalized linear regression algorithm: a random forest algorithm: a support vector machine algorithm: a gradient boosting regression algorithm: a decision tree algorithm: a generalized additive model: evolutionary programming algorithms; Bayesian inference algorithms, reinforcement learning algorithms, and the like. However, generalized linear regression algorithms, random forest algorithms, support vector machine algorithms, gradient boosting regression algorithms, decision tree algorithms, generalized additive models, and the like may be preferred over neural network algorithms, deep learning algorithms, evolutionary programming algorithms, and the like, in some public-safety environments, such as PSAP environments, and the like. Any suitable machine learning algorithm and/or deep learning algorithm and/or neural network is within the scope of present examples. For example, such machine learning algorithms may be trained to determine threshold temperatures and/or threshold impedances and/or auxiliary currents.

As depicted, the device 100 further comprises an integrated circuit 222 adjacent the at least one electrical circuit 220, and a second temperature measurement device 224, configured to measure the temperature of the device 100 (e.g., rather than the battery cell 200) and, in particular, a temperature of one or more of the at least one electrical circuit 220 and the integrated circuit 222. In some examples, the integrated circuit 222 may comprise a memory, such as the static memory 212, or another memory. It is understood that one or more of the at least one electrical circuit 220 and the integrated circuit 222 may not function normally and/or properly, and/or may have reduced functionality at temperatures below a respective threshold temperature.

As such, the temperature of one or more of the at least one electrical circuit 220 and the integrated circuit 222 may be measured by the second temperature measurement device 224, and the controller 208 may implement the blocks of the method set forth in FIG. 4 to control the at least one electrical circuit 220 to enter a heating mode to cause the respective temperature of one or more the at least one electrical circuit 220 and the integrated circuit 222 to increase.

As depicted, however, some types of integrated circuits 222, and the second temperature measurement device 224, may be optional and hence the integrated circuit 222 and the second temperature measurement device 224 are depicted in dashed lines. Indeed, controlling the at least one electrical circuit 220 to enter a heating mode may be optional, and/or may be implemented independent of controlling the at least one electrical circuit 220 to enter the low efficiency mode described herein.

Attention is now directed to FIG. 3, which depicts a flowchart representative of a method 300 to control at least one electrical circuit to enter a low efficiency mode to heat a battery cell. The operations of the method 300 of FIG. 3 correspond to machine readable instructions that are executed by the device 100, and specifically the controller 208 of the device 100. In the illustrated example, the instructions represented by the blocks of FIG. 3 are stored at the memory 212 for example, as the application 214. The method 300 of FIG. 3 is one way that the controller 208 and/or the device 100 may be configured. Furthermore, the following discussion of the method 300 of FIG. 3 will lead to a further understanding of the device 100, and its various components.

The method 300 of FIG. 3 need not be performed in the exact sequence as shown and likewise various blocks may be performed in parallel rather than in sequence. Accordingly, the elements of method 300 are referred to herein as “blocks” rather than “steps.” The method 300 of FIG. 3 may be implemented on variations of the device 100 of FIG. 1, as well.

At a block 302, the controller 208, and/or the device 100, determines, via the temperature measurement device 204, the temperature of the battery cell 200. For example, the controller 208 may receive the temperature of the battery cell 200 from the temperature measurement device 204.

At a block 304, the controller 208, and/or the device 100 determines, via the battery cell parameter determination device 206, the impedance of the battery cell 200. For example, the controller 208 may receive the impedance of the battery cell 200 from the battery cell parameter determination device 206.

At an optional block 306, the controller 208, and/or the device 100 determines, via the battery cell parameter determination device 206, the voltage and/or the charge capacity of the battery cell 200. The optionality of the block 306 is indicated by the block 306 being drawn in dashed lines. For example, the controller 208 may receive the voltage and/or the charge capacity of the battery cell 200 from the battery cell parameter determination device 206.

At a block 308, the controller 208, and/or the device 100 determines whether the temperature of the battery cell 200 is below a threshold temperature. As described herein, the threshold temperature may depend on a type of the battery cell 200, which may be read from a memory (not depicted) of the battery 202 via a data connection, and determined from the table 221. Alternatively, and/or in addition, a threshold temperature of the battery cell 200 may be determined heuristically, for example by measuring lifetimes of battery cells at different temperatures and a threshold temperature may comprise a temperature, below which a lifetime of the battery cell 200 may be unacceptably low. While such “unacceptability” is understood to be relative, an unacceptably low lifetime (e.g., a time period that the battery cell 200 is able to power the device 100) may be 1 minute, 10 minutes, 20 minutes, 30 minutes, amongst other possibilities.

In some examples, the threshold temperature may be −10° C., −15° C., −20° C., amongst other possibilities.

At a block 310, the controller 208, and/or the device 100 determines whether the impedance of the battery cell 200 is above a threshold impedance.

Similar to the threshold temperature, the threshold impedance may be determined heuristically, and may depend on a type of the battery cell 200. For example, the threshold impedance may be 0.6 ohms, 1 ohm, 1.2 ohms, amongst other possibilities.

While heretofore the temperature of the battery cell 200 being below the threshold temperature, and the impedance of the battery cell 200 being above the threshold impedance has been described as occurring simultaneously, in some instances an impedance of a battery cell 200 may not be above the threshold impedance when the temperature of the battery cell 200 is below the threshold temperature. For example, due to manufacturing variances, and the like, some battery cells 200 may experience increases in impedance at a slower rate, as temperature decreases, as compared to other battery cells 200. Hence, both the block 308 and the block 310 may be implemented to determine whether the temperature of the battery cell 200 is below the threshold temperature and whether the impedance of the battery cell 200 is above the threshold impedance.

At an optional block 312, the controller 208, and/or the device 100 determines whether the voltage and/or the charge capacity of the battery cell 200 is respectively above a threshold voltage and/or a threshold charge capacity. For example, the battery cell 200 may be rated at a particular voltage, such as 12V, and when the voltage of the battery cell 200 falls below a threshold voltage, the battery cell 200 may need to be changed, as the battery cell 200 may no longer be capable of providing sufficient charge to power the device 100.

Similarly, a charge capacity of the battery cell 200 is understood to reduce over time, and when the charge capacity of the battery cell 200 falls below a threshold charge capacity, the battery cell 200 may need to be changed, as the battery cell 200 may no longer be capable of providing sufficient charge to power the device 100

As such, the optional block 312 may be implemented to ensure that the battery cell 200 has sufficient voltage and/or charge capacity to operate the device 100. In particular, when the voltage and/or the charge capacity of the battery cell 200 is respectively below a threshold voltage and/or a threshold charge capacity (e.g., a “NO” decision at the block 312), at an optional block 314, the controller 208 and/or the device 100 may control the display screen 102 to provide an indication message to change the battery, and the method 300 may repeat from the block 302. However, in other examples, the optional block 314 may not occur and/or the controller 208 and/or the device 100 may control the display screen 102 to provide an indication that the battery cell 200 may have shortened life due to a temperature thereof, and/or an indication that a low efficiency mode and/or battery cell heating is not available.

In some examples, the threshold voltage may be determined heuristically, and/or the threshold voltage may depend on for example a type of the battery cell 200. For example, a threshold voltage may comprise 95% of a voltage rating of the battery cell 200, 90% of the voltage rating of the battery cell 200, 85% of the voltage rating of the battery cell 200, amongst other possibilities. Regardless, it is understood that the voltage rating may be read from a memory of the battery 202. Furthermore it is understood that, below the threshold voltage, the device 100 may not function, and/or may only partially function, and that above the threshold voltage, the device 100 may function normally.

Similarly, the threshold charge capacity may be determined heuristically, and/or the threshold charge capacity may depend on for example a type of the battery cell 200. For example, a threshold charge capacity may comprise 95% of a charge capacity of the battery cell 200, 90% of the charge capacity of the battery cell 200, 85% of the charge capacity of the battery cell 200, amongst other possibilities. Regardless, it is understood that the charge capacity may be read from a memory of the battery 202, for example via a data connection with the battery 202. Furthermore it is understood that, below the threshold charge capacity, the device 100 may not function, and/or may only partially function, and that above the threshold charge capacity, the device 100 may function normally.

Alternatively, and/or in addition, and with reference to Equation (3), the threshold voltage may comprise a voltage that is greater than VoutAux+IAux×Rbat, for example when the auxiliary current IAux is predetermined for a measured battery impedance. Rbat, for example as stored at the table 221.

Returning briefly to the block 308 and the block 310, when the temperature of the battery cell 200 is above the threshold temperature (e.g., a “NO” decision at the block 308) or the impedance of the battery cell 200 is below the threshold impedance (e.g., a “NO” decision at the block 310), the method 300 may repeat from block 302.

However, when the temperature of the battery cell 200 is below the threshold temperature (e.g., a “YES” decision at the block 308) and the impedance of the battery cell 200 is above the threshold impedance (e.g., a “YES” decision at the block 310) (and, optionally, when the voltage of the battery cell 200 is above the threshold voltage and/or the charge capacity of the battery cell 200 is above the threshold charge capacity, a “YES” decision at the block 312 when implemented), at a block 316, the controller 208 and/or the device 100 controls the at least one electrical circuit 220 to enter a low efficiency mode by controlling the at least one electrical circuit 220 to draw an auxiliary current from the battery cell 200 to heat the battery cell 200, the auxiliary current being below the given functional operating current, the at least one electrical circuit 220 having reduced functionality, relative to a given functionality of the at least one electrical circuit 220, while drawing the auxiliary current.

In particular, the controller 208 may generally control the at least one electrical circuit 220 to draw the auxiliary current based on the measured impedance of the battery cell 200, for example to achieve a particular IR loss at the battery cell 200. For example, when the impedance of the battery cell 200 is known, an IR loss of the battery cell 200 is understood to be current multiplied impedance (e.g., resistance), or IR (e.g., where “I” is current and/or the auxiliary current, and “R” is impedance and/or resistance, similar to Rbat of the Equations (1), (2), (3)), and the amount of heat by the battery cell 200 is hence understood to depend on a selected auxiliary current.

While the battery cell 200 may also provide heat when the at least one electrical circuit 220 is operated at the given functional operating current, drawing the given functional operating current from the battery cell 200 may cause the battery tripping circuit 203 to trip at the increased impedance of the battery cell 200, and/or the device 100 may fail as the IR loss at the battery cell 200 may cause all components of the device 100, and/or critical components of the device 100 (e.g., such as the controller 208), and/or a portion of the components of the device 100 to turn off as the voltage provided by the battery cell 200 drops below a respective operating voltage of such components.

Put another way, at the block 316, the at least one electrical circuit 220 is operated at an auxiliary current, which is less than a given functional operating current, which may cause the at least one electrical circuit 220 to operate at reduced functionality, but which generally causes the temperature of the battery cell 200 to increase, and without causing the battery tripping circuit 203 to trip and/or without causing the voltage provided by the battery cell 200 to other components of the device 100, to drop below a respective operating voltage.

In some examples, depending on a type of the at least one electrical circuit 220, the at least one electrical circuit 220 may not be “off”, and/or may not be providing given functionality, prior to being operated in the low efficiency mode.

For example, when the at least one electrical circuit 220 comprises an amplifier, such an RF transmit amplifier or an audio (e.g., RF receive) amplifier, in the low efficiency mode, biasing of such an amplifier (e.g., biasing of a MOSFET thereof) may be turned “on” by the controller 208 and/or the device 100, for example by controlling biasing components of the amplifier to draw the auxiliary current from the battery cell 200.

At a block 316, the controller 208 and/or the device 100 may control the at least one electrical circuit 220 to exit the low efficiency mode in any suitable manner as in next described.

For example, the method 300 may further comprise, the controller 208 and/or the device 100 controlling the at least one electrical circuit 220 to exit the low efficiency mode after a given time period. Such a given time period may comprise 10 seconds, 30 seconds, 1 minute, 5 minutes, amongst other possibilities. The given time period may be determined heuristically and is understood to comprise a time that has been determined to be sufficient to cause the impedance of the battery cell 200 to reach, or fall below, the threshold impedance. Furthermore, the given time period may depend on an initial temperature of the battery cell 200: in particular, the given time period may be longer with colder temperatures, and shorter with higher temperatures,

Alternatively, and/or in addition, the method 300 may further comprise, the controller 208 and/or the device 100 controlling the at least one electrical circuit 220 to exit the low efficiency mode when the impedance of the battery cell 200 reaches, or falls below, the threshold impedance. In these examples, the method 300 may comprise the controller 208 and/or the device 100: while the at least one electrical circuit 220 is in the low efficiency mode, again measuring the impedance of the battery cell 200 (e.g., periodically, and the like), and controlling the at least one electrical circuit 220 to exit the low efficiency mode when the impedance of the battery cell 200 reaches, or falls below, the threshold impedance.

Alternatively, and/or in addition, the method 300 may further comprise, the controller 208 and/or the device 100 controlling the at least one electrical circuit 220 to exit the low efficiency mode when the temperature of the battery cell 200 reaches, or rises above, the threshold impedance. In these examples, the method 300 may comprise the controller 208 and/or the device 100: while the at least one electrical circuit 220 is in the low efficiency mode, again measuring the temperature of the battery cell 200 (e.g., periodically, and the like), and controlling the at least one electrical circuit 220 to exit the low efficiency mode when the temperature of the battery cell 200 reaches, or rises above, the threshold impedance.

Other features are within the scope of the method 300 and/or the device 100.

For example, the method 300 may further comprise, the controller 208 and/or the device 100: while the at least one electrical circuit 220 is in the low efficiency mode, again measuring (e.g., periodically, and the like) the impedance of the battery cell 200; and as the impedance of the battery cell 200 decreases, controlling the auxiliary current to increase. For example, while the at least one electrical circuit 220 is in the low efficiency mode, the IR loss in the battery cell 200 may cause the temperature of the battery cell 200 to increase, decreasing the impedance of the battery cell 200. As such, the IR loss in the battery cell 200 may decrease, which further decreases heating of the battery cell 200. Hence, the auxiliary current may be increased as the impedance of the battery cell 200 decreases to about maintain the IR loss, however such an increase in the auxiliary current may occur using similar constraints on the auxiliary current as has been previously described herein.

In yet further examples, the method 300 may further comprise, the controller 208 and/or the device 100 controlling the at least one electrical circuit 220 to enter or exit the low efficiency mode, depending on a type of the at least one electrical circuit 220 and/or events which may occur at the device 100, as is next described.

For example, when the at least one electrical circuit 220 comprises an RF transmit amplifier, the method 300 may further comprise the controller 208 and/or the device 100, determining that an RF transmit event is occurring; and delaying controlling the RF transmit amplifier to enter the low efficiency mode until the RF transmit event is completed. For example, an RF transmit event may be indicated by a PTT button (e.g., the input device 104-2) being actuated at the device 100. Put another way, an RF transmit event may comprise a user of the device 100 operating the device 100 to transmit data, such as voice data. Furthermore, an RF transmit event may comprise the device 100 transmitting data via an RF signal, for example via the communication interface 210. Hence, alternatively, and/or in addition, an RF transmit event may be indicated by the communication interface 210 transmitting an RF signal. Regardless, when a “YES” decision occurs at the blocks 308, 310 (e.g., and at the optional block 312), and the PTT button is actuated during implementation of the method 300, and/or the communication interface 210 transmits an RF signal, the controller 208 and/or the device 100 may delay implementing the block 316 until the PTT button is released and/or the communication interface 210 completes transmission of an RF signal. In this manner, the RF transmit amplifier may operate at full functionality for the RF transmit event, though such operation may result in a shorter lifetime of the battery due to the higher IR loss that occurs due to the higher functional current being drawn by the RF transmit amplifier, as compared to the aforementioned auxiliary current. However, such operation may cause an increase in temperature of the battery cell 200, and hence, in other examples, when the RF transmit event ends, the method 300 may be reimplemented from the block 302.

In yet further examples, when the at least one electrical circuit 220 comprises an RF transmit amplifier, the method 300 may further comprise the controller 208 and/or the device 100: determining that a respective RF transmit event occurs while the RF transmit amplifier is in the low efficiency mode; and controlling the RF transmit amplifier to exit the low efficiency mode. In this manner, full functionality of the RF transmit amplifier may be restored for the respective RF transmit event.

In yet further examples, when the at least one electrical circuit 220 comprises an audio amplifier, the method 300 may further comprise the controller 208 and/or the device 100: determining that an RF receive event is occurring; and delaying controlling the at least one electrical circuit 220 to enter the low efficiency mode until the RF receive event is completed. For example, an RF receive event may comprise the communication interface 210 receiving an RF signal, such as voice data received from another device and/or another radio via the communication interface 210. Regardless, when a “YES” decision occurs at the blocks 308, 310 (e.g., and at the optional block 312), and the communication interface 210 receives an RF signal, the controller 208 and/or the device 100 may delay implementing the block 316 until the communication interface 210 completes receipt of the RF signal. In this manner, the audio amplifier may operate at full functionality for the RF receive event, though such operation may result in a shorter lifetime of the battery due to the higher IR loss that occurs due to the higher functional current being drawn by the audio amplifier, as compared to the aforementioned auxiliary current. However, such operation may cause an increase in temperature of the battery cell 200, and hence, in other examples, when the RF receive event ends, the method 300 may be reimplemented from the block 302.

In yet further examples, when the at least one electrical circuit 220 comprises an audio amplifier, the method 300 may further comprise the controller 208 and/or the device 100: determining that a respective RF receive event occurs while the audio amplifier is in the low efficiency mode; and controlling the audio amplifier to exit the low efficiency mode. In this manner, full functionality of the audio amplifier may be restored for the respective RF receive event.

In yet further examples, prior to implementing the block 316 (e.g., and after “YES” decisions at the blocks 308, 310 (and optionally the block 312)), the controller 208 and/or the device 100 may control the display screen 102 to provide a graphic user interface (GUI) inquiring as to whether the battery cell 200 should be heated. Such a GUI may include selectable electronic buttons, and the like, which, when selected, causes the block 316 to be implemented, or not. An example of such a GUI is depicted in FIG. 8.

Attention is next directed to FIG. 4, which depicts a flowchart representative of a method 400 to control at least one electrical circuit to enter a heating mode to heat one or more of the at least one electrical circuit and an integrated circuit adjacent the at least one electrical circuit. The operations of the method 400 of FIG. 4 correspond to machine readable instructions that are executed by the device 100, and specifically the controller 208 of the device 100. In the illustrated example, the instructions represented by the blocks of FIG. 4 are stored at the memory 212 for example, as the application 214. The method 400 of FIG. 4 is one way that the controller 208 and/or the device 100 may be configured. Furthermore, the following discussion of the method 400 of FIG. 4 will lead to a further understanding of the device 100, and its various components.

The method 400 of FIG. 4 need not be performed in the exact sequence as shown and likewise various blocks may be performed in parallel rather than in sequence. Accordingly, the elements of method 400 are referred to herein as “blocks” rather than “steps.” The method 400 of FIG. 4 may be implemented on variations of the device 100 of FIG. 1, as well.

It is further understood that the method 400 may be implemented in conjunction with the method 300 or independent of the method 300. Put another way, in some examples of the device 100, the method 400 may be implemented, but not the method 300. However, in other examples of the device 100, the method 300 may be implemented, but not the method 400.

For implementation of the method 400, however, it is understood that the device 100 further comprises the second temperature measurement device 224 configured to measure a respective temperature of one or more of the at least one electrical circuit 220 and the integrated circuit 222 is adjacent the at least one electrical circuit 220.

At a block 402, the controller 208 and/or the device 100 determines, via the second temperature measurement device 224, a respective temperature of one or more the at least one electrical circuit 220 and the integrated circuit 222. For example, the controller 208 may receive, the respective temperature of one or more the at least one electrical circuit 220 and the integrated circuit 222 via the second temperature measurement device 224.

At a block 404, the controller 208 and/or the device 100 determines whether the respective temperature of one or more the at least one electrical circuit 220 and the integrated circuit 222 is below a respective threshold temperature. The respective threshold temperature may be determined heuristically, for example by measuring functionality of the at least one electrical circuit 220 and/or the integrated circuit 222 at different temperatures, and determining a temperature, below which functionality of the at least one electrical circuit 220 and/or the integrated circuit 222 is affected and/or is reduced. The respective threshold temperature may be set to about such a temperature, and the like. In some examples, the respective threshold temperature may be −10° C., −15° C., −20° C., amongst other possibilities.

When the respective temperature of one or more the at least one electrical circuit 220 and the integrated circuit 222 is not below the respective threshold temperature (e.g., a “NO” decision at the block 404), the controller 208 and/or the device 100 continues to implement the method 400 from the block 402.

When the respective temperature of one or more the at least one electrical circuit 220 and the integrated circuit 222 is below the respective threshold temperature (e.g., a “YES” decision at the block 404), at a block 406, the controller 208 and/or the device 100 controls the at least one electrical circuit 220 to enter a heating mode, in which one or more of power consumption, voltage output, current consumption and frequency increases, to cause the respective temperature of one or more the at least one electrical circuit 220 and the integrated circuit 222 to increase.

For example, in a general “normal” operating mode (e.g., at the given functional operating current and a functional voltage) the at least one electrical circuit 220 may provide given functionality. However, by increasing power consumption and/or voltage output (e.g., when the at least one electrical circuit 220 comprises an amplifier) and/or current consumption and/or frequency (e.g., when the at least one electrical circuit 220 comprises a processor), relative to when the at least one electrical circuit 220 is in the “normal” operating mode, the at least one electrical circuit 220 may emit more heat than in the “normal” operating mode, thereby increasing a temperature of the at least one electrical circuit 220 and/or a temperature of the integrated circuit 222. For example, when the integrated circuit 222 is adjacent the at least one electrical circuit 220 that is emitting heat, both the at least one electrical circuit 220 and the integrated circuit 222 may increase in temperature.

In some examples, in the heating mode, the at least one electrical circuit 220 may continue to provide the given functionality, or, in the heating mode, the at least one electrical circuit 220 may not provide the given functionality and/or may provide reduced functionality.

At a block 408, the controller 208 and/or the device 100 determines whether the respective temperature reaches, or rises above, the respective threshold temperature.

Similarly, at a block 410, the controller 208 and/or the device 100 determines whether an event occurs in association with the at least one electrical circuit 220, the event requiring the at least one electrical circuit 220 to perform the given functionality, for example of the normal operating mode. As has been described, when the at least one electrical circuit 220 comprises an RF transmit amplifier or an audio amplifier, the event may comprise an RF transmit event or an RF receive event.

When the respective temperature reaches, or rises above, the respective threshold temperature (e.g., a “YES” decision at the block 408) and/or when an event occurs in association with the at least one electrical circuit 220 (e.g., a “YES” decision at the block 410), at a block 412, the controller 208 and/or the device 100 controls the at least one electrical circuit 220 to exit the heating mode, for example to return to the normal operating mode.

It is further understood that, when the respective temperature has not yet reached, or risen above, the respective threshold temperature (e.g., a “NO” decision at the block 408) and when no event occurs in association with the at least one electrical circuit 220 (e.g., a “NO” decision at the block 410), the at least one electrical circuit 220 remains in the heating mode at the block 406.

However, the controller 208 and/or the device 100 may control the at least one electrical circuit 220 to exit the heating mode under other conditions, such as after a given time period, and the like.

Other features are within the scope of the method 400 and/or the device 100.

For example, similar to the method 300, an event may occur in association with the at least one electrical circuit 220, the event requiring the at least one electrical circuit 220 to perform the given functionality, and such an event may occur prior to the block 406 being implemented (e.g., during implementation of the block 402 and/or the block 404). In these examples the controller 208 and/or the device 100 may delay controlling the at least one electrical circuit 220 to enter the heating mode until the event is over.

Furthermore, prior to the controller 208 and/or the device 100 control the at least one electrical circuit 220 to enter the heating mode, the display screen 102 may be controlled to provide a query and/or a GUI as to whether, or not, the at least one electrical circuit 220 should be controlled, or not, to enter the heating mode.

As has been previously described, the method 300 and the method 400 may be implemented independent of each other. For example, the device 100 may be used in a low temperature environment such that both the battery cell 200 and the at least one electrical circuit 220 are below a respective threshold temperature. In these examples, the method 300 may be implemented prior to the method 400 to ensure the impedance of the battery cell 200 is below the threshold impedance before the at least one electrical circuit 220 is heated.

In other examples, the device 100 may be used in a low temperature environment, but a warm battery may be swapped for an old battery, such that the battery cell 200 is above a threshold temperature, but the at least one electrical circuit 220 is below a respective threshold temperature. In these examples, the method 300 may not be implemented and/or “NO” decisions may be made at the blocks 308, 310 of the method 300, but the method 400 may be implemented to heat the at least one electrical circuit 220.

In other examples, the device 100 may be used in a low temperature environment, and the method 300 may be implemented, but not the method 400 and/or implementation of the method 300 may cause the at least one electrical circuit 220 to heat to above respective threshold temperature. In these examples, the method 400 may not be implemented and/or “NO” decisions may be made at the block 404 of the method 400.

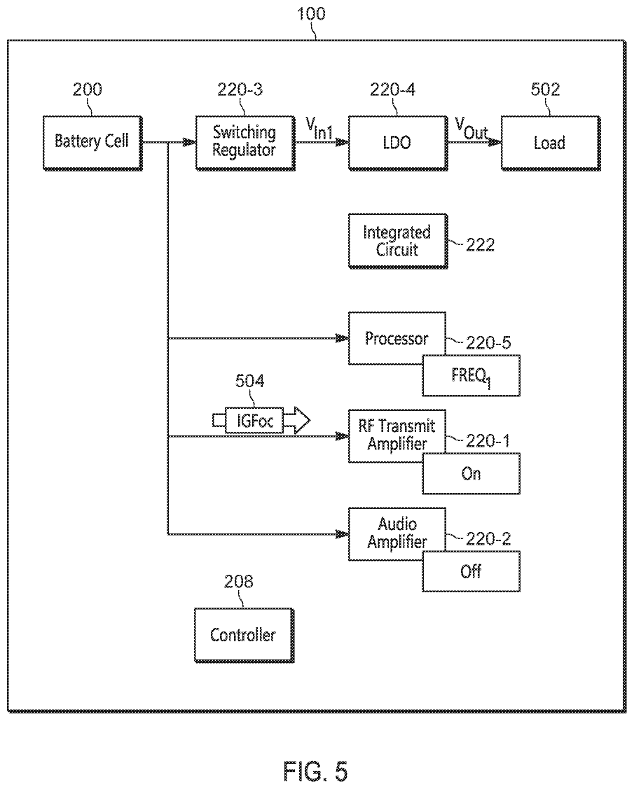

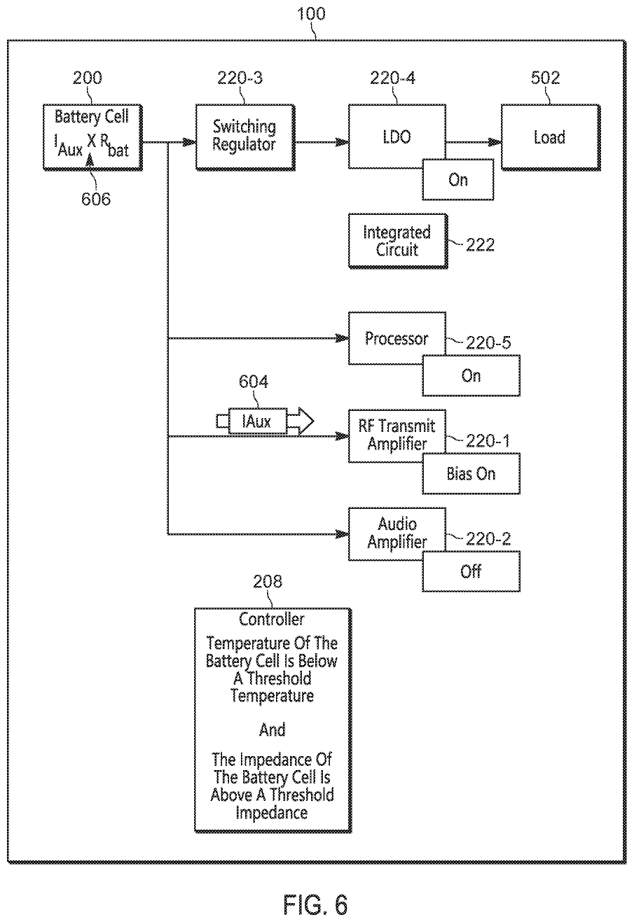

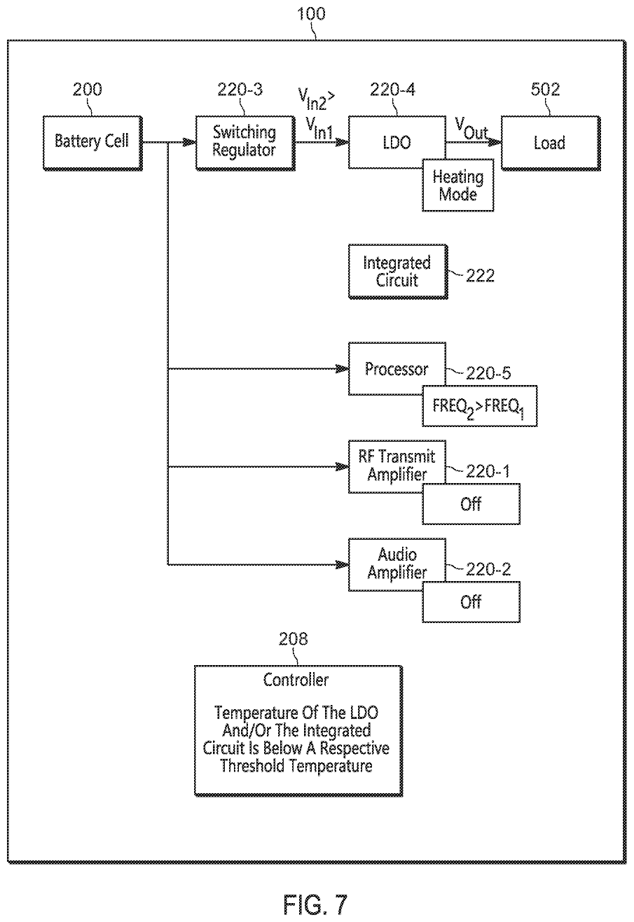

Attention is next directed to FIG. 5, FIG. 6, and FIG. 7, which depict an example of the method 300 and the method 400. In particular, FIG. 5, FIG. 6, and FIG. 7 depict a specific example of the device 100, and depict only certain components of the device 100 as depicted in FIG. 2, though the components depicted in FIG. 2 are understood to be present, as described herein.

In particular, FIG. 5, FIG. 6, and FIG. 7 depicts the battery cell 200 connected to, and hence configured to provide power to, a plurality of electrical circuits 220 including (but not limited to), an RF transmit amplifier 220-1, an audio amplifier 220-2, a switching regulator 220-3, a low-dropout regulator (LDO) 220-4, and a processor 220-5.

FIG. 5, FIG. 6, and FIG. 7 further depict the controller 208 and the integrated circuit 222. For simplicity, the controller 208 and the integrated circuit 222 are not shown as being connected to other components of the device 100, but they are nonetheless understood to be powered by the battery cell 200. Furthermore, the controller 208 is understood to be controlling the plurality of electrical circuits 220 as described herein.

The integrated circuit 222 is further depicted as being adjacent the LDO 220-3 and the processor 220-5.

While the temperature measurement devices 204, 224, the battery cell parameter determination device 206, etc., are not depicted, they are nonetheless understood to be present, as well as other components of the device 100 described with reference to FIG. 2.

FIG. 5 depicts an example of the device 100 in a “normal” operating mode, FIG. 6 depicts an example of the device 100 implementing the method 300, and FIG. 7 depicts an example of the device 100 implementing the method 400.

With reference to FIG. 5, switching regulator 220-3 is understood to receive power from the battery cell 200, and regulate such power to the LDO 220-3, which regulates power to a load 502 of the device 100, which may comprise a at least portion of a radio and/or the communication interface 210 (e.g., a transceiver thereof), a camera, and/or any other suitable component of the device 100. Put another way, the load 502 may comprise an electrical load of a component of the device. Furthermore, while only one LDO 220-3 and one load 502 is depicted, the device 100 may comprise a plurality of LDOs 220-3 and a plurality of respective loads 502. Hence, the switching regulator 220-3 may regulate power for a plurality of LDOs 220-3, which in turn may regulate power for a plurality of respective loads 502.

In particular, as depicted, the switching regulator 220-3 is receiving power from the battery cell 200, and inputting a voltage “V In1” (e.g., and a respective current, not depicted) to the LDO 220-4, and the LDO 220-4 is outputting a voltage “VOut” (e.g., and a respective current, not depicted) to the load 502. At least the input voltage “VIn1” is understood to comprise a voltage input to the LDO 220-4, for example by the switching regulator 220-2, in the normal operating mode.

As further depicted, the RF transmit amplifier 220-1 is “on” (e.g., as an RF transmit event may be occurring) and is drawing a given functional operating current 504, IGFoc, from the battery cell 200, and the audio amplifier 220-3 is “off” (e.g., as an RF receive event may not be occurring). However, whether the amplifiers 220-1, 220-2 are “on” or “off” is understood to depend on whether RF events are occurring at the device 100, and hence, the amplifiers 220-1, 220-2 may be in any suitable state.

Furthermore, the processor 220-5 is operating a given frequency “FREQ1”, which is understood to comprise a frequency of the processor 220-5 in the normal operating mode.

Attention is next directed to FIG. 6, which depicts aspects of the method 300 being implemented at the device 100. In particular, in FIG. 6, the controller 208 is understood to have determined a temperature and impedance, Rbat, of the battery cell 200 (e.g., at the blocks 302, 304 of the method 300). Furthermore, the controller 208 is depicted as determining that the temperature of the battery cell 200 is below a threshold temperature (e.g., a “YES” decision at the block 308 of the method 300), and further determining that the impedance of the battery cell 200 is above a threshold impedance (e.g., a “YES” decision at the block 310 of the method 300). While the blocks 306, 312 are not depicted as being implemented it is understood in FIG. 6 that the controller 208 may implement the blocks 306, 312 and determine a “YES” decision at the block 312.

Hence, as depicted, the controller 208 has controlled the RF transmit amplifier 220-1 to a low efficiency state (e.g., at the block 316 of the method 300) by controlling the RF transmit amplifier 220-1 to draw an auxiliary current 604, IAux, from the battery cell 200, the auxiliary current 604 being less than the given functional operating current 504, for example as described with respect to Equation (2) and Equation (3).

Furthermore, as depicted, such control may occur by turning a bias of the RF transmit amplifier 220-1 “on”. As such, the battery cell 200 has an IR loss 606 of IAux×Rbat, which causes heating of the battery cell 200.

The remainder of the electrical circuits 220 may be on or off, for example according to whether or not they provide certain types of respective functionality to the device 100. For example, as depicted, the LDO 220-4 and the processor 220-5 may both be “on” and in a “normal” operating mode, drawing a respective given functional operating current from the battery cell 200, for example as the LDO 220-4 and the processor 220-5 may provide crucial functionality to the device 100. However, as depicted, the audio amplifier 220-2 may be “off”, and may not turn on until the RF transmit amplifier 220-1 exits the low efficiency state (e.g., at the block 318) and the device 100 enters a normal operating mode similar to that depicted in FIG. 5.

While only the RF transmit amplifier 220-1 is depicted in a low efficiency state in FIG. 6, any suitable number of the electrical circuits 220 may be controlled to a low efficiency state. For example, rather than being merely “on”, one or more of the LDO 220-4 and the processor 220-5 may also be controlled to a low efficiency state, and/or the audio amplifier 220-2 may be controlled to a low efficiency state.

Attention is next directed to FIG. 7, which depicts aspects of the method 400 being implemented at the device 100.

In particular, in FIG. 7, the controller 208 is understood to have determined a temperature and LDO 220-4 and/or the integrated circuit 222 (e.g., at the block 402 of the method 400). Furthermore, the controller 208 is depicted as determining that the temperature of the LDO 220-4 and/or the integrated circuit 222 is below a respective threshold temperature (e.g., a “YES” decision at the block 404 of the method 400).

Hence, as depicted, the controller 208 has controlled the LDO 220-4 to enter a heating mode (e.g., at the block 406 of the method 400) by controlling the input voltage of the LDO 220-4 to a voltage VIn2 that is higher than the input voltage VIn1 of the normal operating mode depicted in FIG. 5. The higher input voltage, VIn2, as compared to the “normal” input voltage VIn1, will generally lead to a higher current draw from the battery cell 200, and hence higher power consumption at the LDO 220-4, causing heat generation of the LDO 220-4 to increase, relative to the normal operating mode. As depicted, the output voltage may not change.

Indeed, it is understood that power dissipated in the LDO 220-4 according to:

$$P ( power dissipate as heat ) = ( V In - V Out ) * I \qquad Equation ( 4 )$$

In Equation (4), “P” is power consumption, at least a portion of which may be dissipated as heat, “I” is current through the LDO 220-4, “VIn” is an input voltage provided by the switching regulator 220-3, and “VOut” is voltage output by the LDO 220-4. Hence, when “VIn” increases from “VIn1” as in FIG. 5, to “VIn2”, as in FIG. 7, power dissipation by the LDO 220-4 increases, as does heat output by the LDO 220-4. Furthermore, to cause the input voltage to the LDO 220-4 to increase, the controller 208 may control the switching regulator to increase the input voltage to the LDO 220-4.

Similarly, in FIG. 7, the controller 208 has controlled the processor 220-5 to enter a heating mode (e.g., at the block 406 of the method 400) by controlling a frequency of the processor 220-5 to increase to a frequency, Freq2, that is higher than the frequency, Freq1, voltage of the normal operating mode depicted in FIG. 5. The higher frequency, Freq2, as compared to the frequency, Freq1, will generally lead to a higher current draw from the processor 220-5, and hence higher power consumption at the processor 220-5, causing heat generation of the processor 220-5 to increase, relative to the normal operating mode.

As such, the LDO 220-4 and the processor 220-5 emit heat, which heats the LDO 220-4, the processor 220-5, and the integrated circuit 222.

It is further understood that controlling the LDO 220-4 and/or the processor 220-5 to enter a heating mode will also increase the temperature of the battery cell 200, which may also reduce the impedance.

It is further understood that the device 100 may return to the normal operating mode depicted in FIG. 5, and the like, when a “YES” decision occurs at the block 408 and/or the block 410, and/or under any other suitable conditions.

In this manner, heating of components of device 100 may occur, to cause the components to operate more efficiently, which increase an operating life of the device 100.

Attention is next directed to FIG. 8, which is substantially similar to FIG. 1, with like components, having like numbers. A left hand side of FIG. 8 depicts an example of the device 100, prior to the block 316 being implemented, and after “YES” decisions at the blocks 308, 310 (and optionally the block 312). In particular, the controller 208 and/or the device 100 has controlled the display screen 102 to provide a query, for example in the form of a GUI 800, inquiring (e.g., via text “Heat Battery” as to whether the battery cell 200 should be heated, for example to increase an operating time of the device 100. As depicted, the GUI 800 includes selectable electronic buttons, “YES” and “NO”, which, when selected, respectively causes the block 316 to be implemented, or not. Presuming the electronic buttons “YES” is selected, a right hand side of FIG. 8 shows the GUI 800 updated to show that the battery cell 200 is being heated (e.g., “Battery Heating in Progress”), progress of such heating (e.g., “80%”, which may be a percent increase of temperature of the battery cell 200, as compared to a difference between the threshold temperature and the temperature of the battery cell 200 determined at the block 302, and/or a percent decrease of impedance of the battery cell 200, as compared to a difference between the threshold impedance and the impedance of the battery cell 200 determined at the block 304), as well as a time that has passed since battery cell heating commenced (e.g., “30 Seconds”). While not depicted, when the battery cell heating ends (e.g., at the block 318 of the method 300), the display screen 102 may render an appropriate message at the GUI 800 (e.g., such as “Battery Now Ready For Use, and the like), and/or the device 100 may enter a normal operating mode.

As should be apparent from this detailed description above, the operations and functions of electronic computing devices described herein are sufficiently complex as to require their implementation on a computer system, and cannot be performed, as a practical matter, in the human mind. Electronic computing devices such as set forth herein are understood as requiring and providing speed and accuracy and complexity management that are not obtainable by human mental steps, in addition to the inherently digital nature of such operations (e.g., a human mind cannot interface directly with RAM or other digital storage, cannot heat components, cannot transmit or receive electronic messages, operate machine learning algorithms, and the like).

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “one of”, without a more limiting modifier such as “only one of”, and when applied herein to two or more subsequently defined options such as “one of A and B” should be construed to mean an existence of any one of the options in the list alone (e.g., A alone or B alone) or any combination of two or more of the options in the list (e.g., A and B together). Similarly the terms “at least one of” and “one or more of”, without a more limiting modifier such as “only one of”, and when applied herein to two or more subsequently defined options such as “at least one of A or B”, or “one or more of A or B” should be construed to mean an existence of any one of the options in the list alone (e.g., A alone or B alone) or any combination of two or more of the options in the list (e.g., A and B together).

A device or structure that is “configured” in a certain way is configured in at least that way, but may also be configured in ways that are not listed.

The terms “coupled”, “coupling” or “connected” as used herein can have several different meanings depending on the context, in which these terms are used. For example, the terms coupled, coupling, or connected can have a mechanical or electrical connotation. For example, as used herein, the terms coupled, coupling, or connected can indicate that two elements or devices are directly connected to one another or connected to one another through intermediate elements or devices via an electrical element, electrical signal or a mechanical element depending on the particular context.

It will be appreciated that some embodiments may be comprised of one or more generic or specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Moreover, an embodiment can be implemented as a computer-readable storage medium having computer readable code stored thereon for programming a computer (e.g., comprising a processor) to perform a method as described and claimed herein. Any suitable computer-usable or computer readable medium may be utilized. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory. In the context of this document, a computer-usable or computer-readable medium may be any medium that can contain, store, communicate, propagate, or transport the program for use by or in connection with the instruction execution system, apparatus, or device.

Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation. For example, computer program code for carrying out operations of various example embodiments may be written in an object oriented programming language such as Java, Smalltalk, C++, Python, or the like. However, the computer program code for carrying out operations of various example embodiments may also be written in conventional procedural programming languages, such as the “C” programming language or similar programming languages. The program code may execute entirely on a computer, partly on the computer, as a stand-alone software package, partly on the computer and partly on a remote computer or server or entirely on the remote computer or server. In the latter scenario, the remote computer or server may be connected to the computer through a local area network (LAN) or a wide area network (WAN), or the connection may be made to an external computer (for example, through the Internet using an Internet Service Provider).

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

What is claimed is:

1. A device comprising:
a battery cell;
at least one electrical circuit configured to provide given functionality when drawing a given functional operating current from the battery cell;
a temperature measurement device configured to measure a temperature of the battery cell;
a battery cell parameter determination device configured to determine at least an impedance of the battery cell; and
a controller configured to:
determine, via the temperature measurement device, the temperature of the battery cell;
determine, via the battery cell parameter determination device, the impedance of the battery cell; and,
when the temperature of the battery cell is below a threshold temperature and the impedance of the battery cell is above a threshold impedance:
control the at least one electrical circuit to enter a low efficiency mode by controlling the at least one electrical circuit to draw an auxiliary current from the battery cell to heat the battery cell, the auxiliary current being below the given functional operating current, the at least one electrical circuit having reduced functionality, relative to the given functionality, while drawing the auxiliary current.

2. The device of claim 1, wherein the battery cell parameter determination device is configured to determine a voltage of the battery cell, and
the controller is further configured to:
determine, via the battery cell parameter determination device, the voltage of the battery cell; and,
when the temperature of the battery cell is below the threshold temperature and the impedance of the battery cell is above the threshold impedance and the voltage of the battery cell is above a threshold voltage:
control the at least one electrical circuit to enter the low efficiency mode.

3. The device of claim 1, wherein the at least one electrical circuit comprises one or more of:
a MOSFET (metal-oxide semiconductor field-effect transistor) with biasing control capability;
a radio-frequency (RF) transmit amplifier;
an audio amplifier;
a regulator;
a baseband processor;
an applications processor; and
an RF integrated circuit synthesizer.

4. The device of claim 1, wherein one or more of the threshold impedance and the auxiliary current is dependent on one or more of the temperature and a type of the battery cell.

5. The device of claim 1, wherein the controller is further configured to:
while the at least one electrical circuit is in the low efficiency mode, again measure the impedance of the battery cell; and
as the impedance of the battery cell decreases, control the auxiliary current to increase.

6. The device of claim 1, wherein the controller is further configured to one or more of:
control the at least one electrical circuit to exit the low efficiency mode after a given time period;
control the at least one electrical circuit to exit the low efficiency mode when the impedance of the battery cell falls reaches, or falls below, the threshold impedance; and
control the at least one electrical circuit to exit the low efficiency mode when the temperature of the battery cell reaches, or rises above, the threshold temperature.

7. The device of claim 1, wherein the controller is further configured to one or more of:
when the at least one electrical circuit comprises an RF transmit amplifier, and an RF transmit event is occurring, delay controlling of the RF transmit amplifier to enter the low efficiency mode until the RF transmit event is completed;
when the at least one electrical circuit comprises the RF transmit amplifier, and a respective RF transmit event occurs while the RF transmit amplifier is in the low efficiency mode, control the RF transmit amplifier to exit the low efficiency mode;
when the at least one electrical circuit comprises an audio amplifier, and an RF receive event is occurring, delay controlling the at least one electrical circuit to enter the low efficiency mode until the RF receive event is completed; and
when the at least one electrical circuit comprises the audio amplifier, and a respective RF receive event occurs while the audio amplifier is in the low efficiency mode, control the audio amplifier to exit the low efficiency mode.

8. The device of claim 1, further comprising a second temperature measurement device configured to measure a respective temperature of one or more of the at least one electrical circuit and an integrated circuit adjacent the at least one electrical circuit, the controller configured to:
when the respective temperature of one or more the at least one electrical circuit and the integrated circuit is below a respective threshold temperature;
control the at least one electrical circuit to enter a heating mode, in which one or more of power consumption, current consumption, voltage output and frequency increases, to cause the respective temperature of one or more the at least one electrical circuit and the integrated circuit to increase; and
control the at least one electrical circuit to exit the heating mode when one or more of:
the respective temperature of one or more the at least one electrical circuit and the integrated circuit reaches, or rises, above the respective threshold temperature; and
an event occurs in association with the at least one electrical circuit, the event requiring the at least one electrical circuit to perform the given functionality.

9. The device of claim 1, wherein the at least one electrical circuit excludes a dedicated battery cell heater and a dedicated device heater.

10. The device of claim 1, further comprising a battery that includes the battery cell, and wherein at least a portion of the battery cell parameter determination device is located external to the battery.

11. A method comprising:
determining, via a temperature measurement device, a temperature of a battery cell of a device;
determining, via a battery cell parameter determination device, an impedance of the battery cell; and,
when the temperature of the battery cell is below a threshold temperature and the impedance of the battery cell is above a threshold impedance:
controlling, via a controller of the device, at least one electrical circuit of the device to enter a low efficiency mode by controlling the at least one electrical circuit to draw an auxiliary current from the battery cell to heat the battery cell, the auxiliary current being below a given functional operating current of the at least one electrical circuit, the at least one electrical circuit having reduced functionality, relative to a given functionality when drawing a given functional operating current from the battery cell, while drawing the auxiliary current.

12. The method of claim 1, wherein the battery cell parameter determination device is configured to determine a voltage of the battery cell, and the method further comprises:
determining, via the battery cell parameter determination device, the voltage of the battery cell; and,
when the temperature of the battery cell is below the threshold temperature and the impedance of the battery cell is above the threshold impedance and the voltage of the battery cell is above a threshold voltage;
controlling, via the controller, the at least one electrical circuit to enter the low efficiency mode.

13. The method of claim 11, wherein the at least one electrical circuit comprises one or more of:
a MOSFET (metal-oxide semiconductor field-effect transistor) with biasing control capability;
a radio-frequency (RF) transmit amplifier;
an audio amplifier;
a regulator;
a baseband processor;
an applications processor; and
an RF integrated circuit synthesizer.

14. The method of claim 11, wherein one or more of the threshold impedance and the auxiliary current is dependent on one or more of the temperature and a type of the battery cell.

15. The method of claim 11, wherein the method further comprises:
while the at least one electrical circuit is in the low efficiency mode, again measuring the impedance of the battery cell; and
as the impedance of the battery cell decreases, controlling the auxiliary current to increase.

16. The method of claim 11, wherein the method further comprises one or more of:
controlling the at least one electrical circuit to exit the low efficiency mode after a given time period;
controlling the at least one electrical circuit to exit the low efficiency mode when the impedance of the battery cell falls reaches, or falls below, the threshold impedance; and
controlling the at least one electrical circuit to exit the low efficiency mode when the temperature of the battery cell reaches, or rises above, the threshold temperature.

17. The method of claim 11, wherein the method further comprises one or more of:
when the at least one electrical circuit comprises an RF transmit amplifier, and an RF transmit event is occurring, delaying controlling of the RF transmit amplifier to enter the low efficiency mode until the RF transmit event is completed;
when the at least one electrical circuit comprises the RF transmit amplifier, and a respective RF transmit event occurs while the RF transmit amplifier is in the low efficiency mode, controlling the RF transmit amplifier to exit the low efficiency mode;
when the at least one electrical circuit comprises an audio amplifier, and an RF receive event is occurring, delay controlling the at least one electrical circuit to enter the low efficiency mode until the RF receive event is completed; and
when the at least one electrical circuit comprises the audio amplifier, and a respective RF receive event occurs while the audio amplifier is in the low efficiency mode, controlling the audio amplifier to exit the low efficiency mode.

18. The method of claim 11, wherein the device further comprises a second temperature measurement device configured to measure a respective temperature of one or more of the at least one electrical circuit and an integrated circuit adjacent the at least one electrical circuit, and the method further comprises:
when the respective temperature of one or more the at least one electrical circuit and the integrated circuit is below a respective threshold temperature:
controlling the at least one electrical circuit to enter a heating mode, in which one or more of power consumption, current consumption, voltage output and frequency increases, to cause the respective temperature of one or more the at least one electrical circuit and the integrated circuit to increase; and
controlling the at least one electrical circuit to exit the heating mode when one or more of:
the respective temperature of one or more the at least one electrical circuit and the integrated circuit reaches, or rises, above the respective threshold temperature; and
an event occurs in association with the at least one electrical circuit, the event requiring the at least one electrical circuit to perform the given functionality.

19. The method of claim 11, wherein the at least one electrical circuit excludes a dedicated battery cell heater and a dedicated device heater.

20. The method of claim 11, wherein the device further comprises a battery that includes the battery cell, and wherein at least a portion of the battery cell parameter determination device is located external to the battery.
